(19) United States
(12) Patent Application Publication
(10) Pub. No.: US 2026/0206364 A1
(43) Pub. Date: Jul. 16, 2026

(54) ROD-TYPE LIGHT EMITTING DEVICE FOR DISPLAY APPARATUS AND METHOD FOR MANUFACTURING SAME

(71) Applicant: ADVANCED VIEW TECHNOLOGY INC., Ansan-si, Gyeonggi-do (KR)

(72) Inventor: Keum-Ju LEE, Ansan-si, Gyeonggi-do (KR)

(73) Assignee: ADVANCED VIEW TECHNOLOGY INC., Ansan-si, Gyeonggi-do (KR)

(21) Appl. No.: 19/133,236

(22) PCT Filed: Oct. 20, 2023
(86) PCT No.: PCT/KR2023/016399

§ 371 Date: May 28, 2025

(30) Foreign Application Priority Data
Dec. 7, 2022 (KR) 10-2022-0169768

(51) Int. Cl. H10H 20/01

(52) U.S. Cl. CPC H10H 20/019; H10H 20/01335; H10H 20/017

(57) ABSTRACT

A method for manufacturing a rod-type light emitting device, includes: sequentially forming a first conductive semiconductor layer, an active layer, and a second conductive semiconductor layer on a substrate; forming a mask pattern on the second conductive semiconductor layer; forming a plurality of rods by etching down to the first conductive semiconductor layer using the mask pattern by a dry etching method; forming an insulating layer on side surfaces of the plurality of rods so as to cover at least the entire longitudinal direction of the active layer; and separating each of the plurality of rods from the substrate.

### CROSS-REFERENCE TO PRIOR APPLICATIONS

This application is a National Stage Patent Application No. PCT/KR2023/016399 (filed on Oct. 20, 2023), which claims priority to Korean Patent Application No. 10-2022-0169768 (filed on Dec. 7, 2022), which are all hereby incorporated by reference in their entirety.

### BACKGROUND

The present disclosure relates to a rod-type light emitting device for a display apparatus.

In addition, the present disclosure relates to a method for manufacturing the rod-type light emitting device.

A display apparatus displays an image by means of a plurality of pixels. Each of such pixels is divided into sub-pixels that emit a single color of the three primary colors of light: red (R), green (G), and blue (B), and all colors ranging from black to white may be expressed by the intensity of each of R, G, and B light.

In order to express all colors in one pixel, a light emitting device that constitutes sub-pixels respectively expressing at least one of R, G, and B is required. Recently, many studies have been conducted to place rod-type light emitting devices, also referred to as micro LEDs, in sub-pixels.

The rod-type light emitting device is manufactured by sequentially forming an n-type nitride semiconductor layer, an active layer, and a p-type nitride semiconductor layer on a growth substrate such as a sapphire substrate, performing an etching process to obtain a plurality of rod-type light emitting devices, and then separating the plurality of rod-type light emitting devices from the growth substrate by a method such as cutting using a cutting tool such as a wire saw or delamination using an adhesive film.

Since the rod-type light emitting device is formed based on a nitride semiconductor such as GaN or AlGaInP, it has excellent durability and lifespan characteristics. In addition, the rod-type light emitting device has advantages of low heat generation and low power consumption due to its small size.

Meanwhile, in order to apply the rod-type light emitting device to a display apparatus, a process of attaching the rod-type light emitting device to a pair of electrodes of the display apparatus is required so that the rod-type light emitting device is electrically connected to the thin-film transistor of each sub-pixel of the display apparatus. Generally, one end of a rod-type light emitting device is connected to a first electrode, and the other end of the rod-type light emitting device is connected to a second electrode. However, due to limitations in the junction area between the rod-type light emitting device and the electrodes, detachment of the rod-type light emitting device may become problematic during the electrode attachment process, and furthermore, during use of a display apparatus employing the rod-type light emitting device, the rod-type light emitting device may detach from the electrodes even with a small impact.

Accordingly, there is a need to increase the bonding strength between the rod-type light emitting device and the electrodes to solve these problems.

Patent Document 1 (Korean Patent Application Publication No. 10-2020-0049946) discloses a method for manufacturing a micro LED chip by applying laser lift-off (LLO). According to the method, a laser beam generated from a laser beam generator sequentially passes through a mask and a glass substrate and melts a sacrificial layer of gallium nitride (GaN) series, whereby the micro LED chip falls. However, in order to apply the laser lift-off method, a sacrificial layer is required, and there is a disadvantage in that the lifetime of a mask or the like becomes short due to the laser beam, so frequent replacement is necessary.

In addition, the micro LED obtained through laser lift-off provides a relatively flat end surface, and such a flat end surface makes it difficult to increase the contact area with the electrodes.

### SUMMARY

An object to be achieved by the present disclosure is to provide a method for manufacturing a rod-type light emitting device for a display apparatus that may increase a contact area with an electrode while simplifying the manufacturing process.

Another object to be achieved by the present disclosure is to provide a rod-type light emitting device for a display apparatus that may increase a contact area with an electrode.

A method for manufacturing a rod-type light emitting device according to an embodiment of the present disclosure for solving the above-described problem comprises: (a) forming a first conductive semiconductor layer, an active layer, and a second conductive semiconductor layer sequentially on a substrate; (b) forming a mask pattern on the second conductive semiconductor layer; (c) etching down to the first conductive semiconductor layer using the mask pattern by a dry etching method to form a plurality of rods; (d) forming an insulating layer on side surfaces of the plurality of rods so as to cover an entire longitudinal direction of at least the active layer; and (e) separating each of the plurality of rods from the substrate, wherein the step (e) comprises inserting a result of the step (d) into a container in which a transducer is coupled and an organic solvent is stored, applying a high frequency from the transducer to the organic solvent to generate a plurality of microbubbles, and separating each of the plurality of rods from the substrate as the plurality of microbubbles gradually penetrate from edges of the plurality of rods their center.

In the step (e), it is preferable that the transducer applies a high frequency of 80 to 160 KHz.

In the step (e), it is preferable that the substrate is inserted into the container such that the plurality of rods face downward.

In the step (e), a height of an end of the plurality of rods adjacent to the substrate may be adjusted to a position of a node of a standing wave.

The first conductive semiconductor layer may be an n-type conductive semiconductor layer, and the second conductive semiconductor layer may be a p-type semiconductor layer. In this case, the step (a) may further include a step of forming a transparent electrode on the second conductive semiconductor layer.

After the step (c), the method may further include a step of additionally etching side surfaces of the plurality of rods by a wet etching method to reduce a difference in lateral size between an upper end and a lower end of the plurality of rods.

In the step (d), the insulating layer may be formed of a material including at least one of silicon oxide (SiO₂), silicon nitride (SiN), silicon oxynitride (SiON), and aluminum oxide (Al₂O₃).

In the step (d), the insulating layer may be formed to include a hydrophobic surface. The insulating layer may include an inorganic insulating layer and an organic insulating layer formed on the inorganic insulating layer, and a terminal of the organic insulating layer may have a hydrophobic functional group. The hydrophobic functional group may include an alkyl group of C1 to C18.

In the step (d), the insulating layer may be formed to cover an entire longitudinal direction of the first conductive semiconductor layer and the second conductive semiconductor layer.

A rod-type light emitting device according to an embodiment of the present disclosure for solving the above problem comprises: a first conductive semiconductor layer; an active layer formed on the first conductive semiconductor layer; and a second semiconductor layer formed on the active layer, wherein a side insulating layer is formed to cover an entire longitudinal direction of the active layer, at least a part of a longitudinal direction of the first conductive semiconductor layer, and at least a part of a longitudinal direction of the second conductive semiconductor layer, and a lower surface of the first conductive semiconductor layer is an uneven surface including irregular portions.

Irregular portions of a lower surface of the first conductive semiconductor layer may be irregular.

The first conductive semiconductor layer may be an n-type conductive semiconductor layer, and the second conductive semiconductor layer may be a p-type semiconductor layer. In this case, a transparent electrode may be further included on the second conductive semiconductor layer.

The insulating layer may include at least one of silicon oxide (SiOₓ), silicon nitride (SiNₓ), silicon oxynitride (SiONₓ), and aluminum oxide (Al₂O₃).

The insulating layer may cover an entire longitudinal direction of the first conductive semiconductor layer and the second conductive semiconductor layer.

The insulating layer may include a hydrophobic surface. The insulating layer may include an inorganic insulating layer and an organic insulating layer formed on the inorganic insulating layer, and a terminal of the organic insulating layer may have a hydrophobic functional group. The hydrophobic functional group may include an alkyl group of C1 to C18.

In the method for manufacturing a rod-type light emitting device for a display apparatus according to the present disclosure, irregular portions may be formed on a lower surface of the first conductive semiconductor layer during the device separation process without adding a separate etching process. Through this, since irregular portions are included on the lower surface of the first conductive semiconductor layer, effects such as improvement in adhesion through enhancement of light extraction efficiency and improvement in contact area with electrodes may be obtained.

In addition, in the method for manufacturing a rod-type light emitting device for a display apparatus according to the present disclosure, high separation yield may be achieved by adjusting the frequency of the transducer and adjusting the height of ends of the plurality of rods corresponding to the separation part from the substrate.

The effect of the present disclosure is not limited to the effects mentioned above, and other effects not mentioned may be clearly understood by those skilled in the art from the following detailed description.

### BRIEF DESCRIPTION OF THE DRAWINGS

FIGS. 1A to 1E are cross-sectional views illustrating a method for manufacturing a rod-type light emitting device for a display apparatus according to the present disclosure.

FIG. 2 schematically illustrates a rod-type light emitting device for a display apparatus according to the present disclosure.

FIGS. 3A, 3B, and 3C are views showing in more detail a portion A-A′ of FIG. 2.

FIG. 4 schematically illustrates a device that may be used in a separation process of a rod-type light emitting device according to an embodiment of the present disclosure.

FIG. 5 is a graph showing separation yield of the rod-type light emitting device according to transducer frequency.

### DESCRIPTION OF REFERENCE NUMERALS

101: substrate
102: undoped semiconductor layer
110: first conductive semiconductor layer (n-type semiconductor layer)
120: active layer
130: second conductive semiconductor layer (p-type semiconductor layer)
140: transparent electrode
150: silicon oxide layer
160: metal pattern
170: side insulating layer

### DETAILED DESCRIPTION

The advantages and features of the present disclosure, and methods for achieving them, will be clearly understood with reference to the embodiments described below in detail together with the accompanying drawings. However, the present disclosure is not limited to the embodiments disclosed below, but may be implemented in various different forms, and these embodiments are provided only to fully disclose the present disclosure and to fully convey the scope of the invention to those skilled in the art to which the present disclosure pertains. The present disclosure is only defined by the scope of the claims.

The expression that an element or a layer is “on” or “under” another element or layer includes not only a case where it is directly on or under the other element or layer but also a case where another layer or element is interposed therebetween. In addition, when an element is described as being “connected to,” “coupled to,” or “attached to” another element, the element may be directly connected, coupled, or attached to the other element, but it should be understood that another element may be “interposed” therebetween or the elements may be “connected,” “coupled,” or “attached” to each other through another element.

The terminology used herein is for the purpose of describing embodiments only and is not intended to limit the present disclosure. In the present specification, the singular forms also include the plural forms unless otherwise specified in the context. The term “include” or “comprise” as used in the specification does not exclude both a case where the composition consists only of the recited elements, components, steps, and/or operations, and a case where one or more other elements, components, steps, and/or operations exist or are added, unless explicitly limited otherwise.

Hereinafter, a rod-type light emitting device for a display apparatus and a method for manufacturing the same according to preferred embodiments of the present disclosure will be described in detail with reference to the accompanying drawings.

In the present disclosure, the rod-type light emitting device may generally have a lateral size, which may be a diameter, diagonal, or width, of 0.1 μm to 5 μm, preferably 0.3 μm to 3 μm, and more preferably 0.5 μm to 1 μm, and a longitudinal size, which may be a length, of 3 μm to 8 μm, more preferably 3 μm to 6 μm, and even more preferably 3 μm to 4 μm, and a length to diameter ratio (aspect ratio) of approximately 5:1 or more, for example, 10:1 or more.

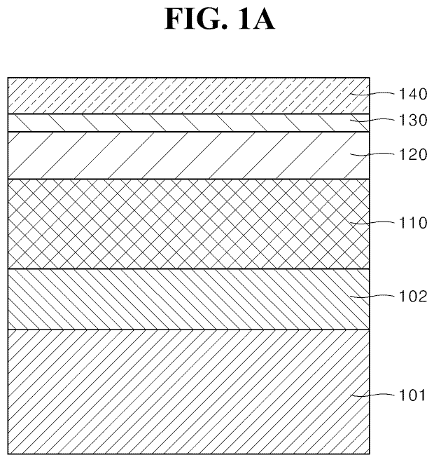

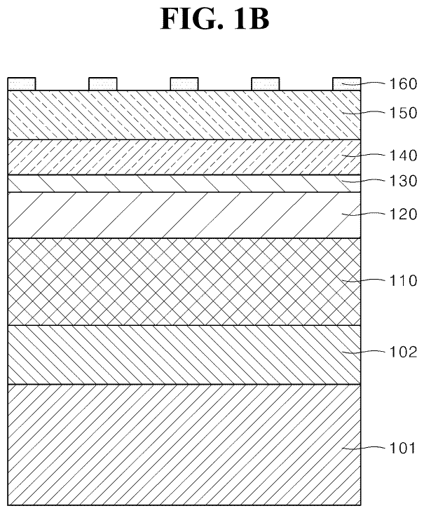

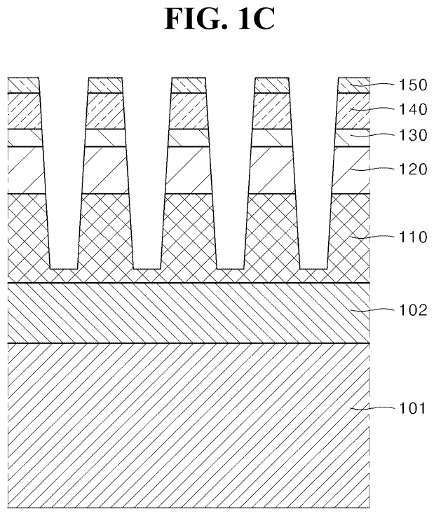

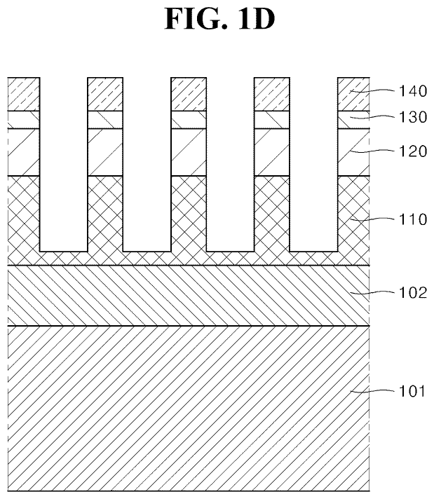

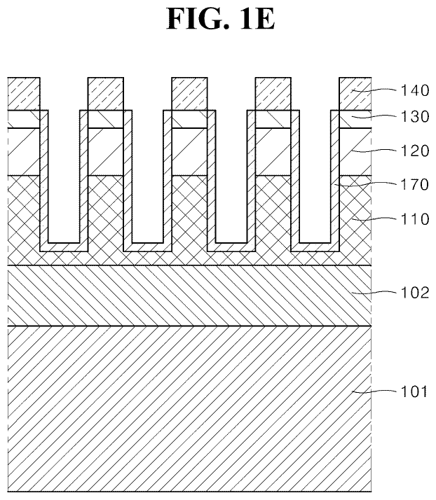

FIGS. 1A to 1E are cross-sectional views illustrating a method for manufacturing a rod-type light emitting device for a display apparatus according to the present disclosure. Specifically, FIG. 1A illustrates an example in which a first conductive semiconductor layer, an active layer, a second conductive semiconductor layer, and a transparent electrode are formed on a substrate; FIG. 1B illustrates an example in which a silicon oxide layer and a chromium pattern are formed as a mask; FIG. 1C illustrates a result of dry etching using the mask; FIG. 1D illustrates a result of etching side surfaces of a plurality of rods by additionally performing wet etching after removing the remaining silicon oxide layer; and FIG. 1E illustrates a result of forming an insulating layer on the side surfaces of the plurality of rods.

Referring first to FIG. 1A, a first conductive semiconductor layer 110, an active layer 120, and a second conductive semiconductor layer 130 are formed on a substrate 101.

As the substrate 101, various known substrates capable of growing semiconductors such as nitride semiconductors may be used, including a sapphire substrate, a silicon substrate, and a GaN substrate. Considering semiconductor growth efficiency and cost, the substrate 101 is most preferably a sapphire substrate.

Between the substrate 101 and the first conductive semiconductor layer 110, a buffer layer (not shown) such as an AlN layer and an undoped semiconductor layer 102 such as undoped GaN may be additionally included to improve crystal quality.

The first conductive semiconductor layer 110, the active layer 120, and the second conductive semiconductor layer 130 are each formed of a semiconductor such as a nitride semiconductor. Each of these may be formed, for example, by a metalorganic chemical vapor deposition (MOCVD) process.

The first conductive semiconductor layer 110 may be an n-type semiconductor layer, and the second conductive semiconductor layer 130 may be a p-type semiconductor layer. For example, the first conductive semiconductor layer 110 may be an n-GaN layer in which an n-type dopant such as Si is doped into a nitride semiconductor such as GaN. For example, the second conductive semiconductor layer 130 may be a p-GaN layer in which a p-type dopant such as Mg is doped into a nitride semiconductor such as GaN.

Alternatively, the first conductive semiconductor layer 110 may be a p-type semiconductor layer, and the second conductive semiconductor layer 130 may be an n-type semiconductor layer.

The active layer 120 may have a multiple quantum well structure in which barrier layers and well layers are alternately stacked. For example, the active layer 120 may be formed by alternately stacking GaN barrier layers and InGaN well layers. In another example, the active layer may be formed by alternately stacking InAlGaN barrier layers and InGaN well layers.

An electron blocking layer (EBL; not shown) may be additionally formed between the active layer 120 and the p-type semiconductor layer (for example, the second conductive semiconductor layer 130) to prevent electron overflow at high current. The electron blocking layer may be formed of a material having a bandgap higher than that of the barrier layer of the active layer 120, and may be, for example, AlGaN.

When the second conductive semiconductor layer 130 is a p-type semiconductor layer, a transparent electrode 140 may be additionally arranged on the second conductive semiconductor layer 130 for current spreading. The transparent electrode 140 may be formed of a transparent conductive oxide such as indium tin oxide (ITO) or fluorine-doped tin oxide (FTO), or a low-resistance material such as graphene.

Next, as shown in the example of FIG. 1B, a mask pattern is formed on the second conductive semiconductor layer 130 (or on the transparent electrode 140, if the transparent electrode 140 is formed).

The mask pattern is for forming a plurality of rods and may include a silicon compound layer 150 and a metal pattern 160, as illustrated in the example of FIG. 1B. For example, one rod may be formed per one metal pattern 160 through subsequent etching.

The silicon compound layer 150 may be formed of silicon oxide, silicon nitride, silicon oxynitride, or the like. The metal pattern 160 may be made of a material such as chromium (Cr) or aluminum (Al). A metal-based mask has an advantage of superior etch selectivity compared to a silicon compound-based mask, so it may etch a target material with a relatively thin thickness.

The thicknesses of the silicon compound layer 150 and the metal pattern 160 may be determined according to the thickness of a target to be etched, that is, the thickness between a lower portion or a specific portion of the first conductive semiconductor layer 110 and an upper portion of the second conductive semiconductor layer (or an upper portion of the transparent electrode, if the transparent electrode is formed), and etching conditions. For example, the thickness of the silicon compound layer 150 may be 0.5 μm to 5 μm, preferably 0.7 μm to 3 μm, and more preferably 1 μm to 1.5 μm. The thickness of the metal pattern 160 may be 200 Å to 1000 Å, preferably 300 Å to 800 Å, and more preferably 400 Å to 600 Å.

Next, dry etching is performed using the mask pattern 150 and 160. Through the dry etching, etching is performed from the second conductive semiconductor layer 130 (or from the transparent electrode 140 if it is formed) down to a part or all of the first conductive semiconductor layer 110. Through this, a plurality of rods having a slightly tapered shape, as illustrated in the example of FIG. 1C, are formed. In the initial stage of etching, for example, the metal pattern 160 withstands sufficiently, and etching is performed in regions between the metal patterns 160. As the etching progresses, the metal pattern 160 no longer withstands and is etched along with other materials, and after the etching is completed, only a small amount of the silicon oxide layer remains. The remaining silicon oxide layer may be removed by a conventional method such as reactive ion etching (RIE).

Meanwhile, after forming only a side insulating layer on the slightly tapered rods illustrated in FIG. 1C, a rod-type light emitting device may be manufactured through a device separation process. If necessary, instead of such a tapered shape, the rods may be made closer to perfect columns having nearly the same lateral size between the upper and lower portions, as illustrated in the example of FIG. 1D. For this purpose, for example, side etching may be performed by wet etching using a tetramethylammonium hydroxide (TMAH) solution.

Next, as illustrated in the example of FIG. 1E, a side insulating layer 170 is formed on side surfaces of the plurality of rods.

The side insulating layer 170 may be formed of silicon oxide (SiO₂), silicon nitride (SiN), silicon oxynitride (SiON), aluminum oxide (Al₂O₃), or the like, and more preferably may be formed of aluminum oxide. The side insulating layer 170 may be formed as a single layer, and if necessary, may be formed as two or more layers. The side insulating layer 170 may be formed of an organic insulating layer in addition to the above-described inorganic insulating layers, or may be formed as a combination of an inorganic insulating layer and an organic insulating layer.

Preferably, the insulating layer 170 may be formed to include a hydrophobic surface. The insulating layer 170 may include an inorganic insulating layer and an organic insulating layer formed on the inorganic insulating layer, and a terminal of the organic insulating layer may have a hydrophobic functional group. The hydrophobic functional group may include an alkyl group of C1 to C18, for example, a methyl group, an ethyl group, or the like. Meanwhile, an end of the organic insulating layer that is attached to the inorganic insulating layer may be formed with a hydrophilic functional group such as a phosphonic acid group to ensure bonding strength.

By forming the side insulating layer 170 on the rod-type light emitting device, current leakage may be suppressed.

The side insulating layer 170 may be formed to cover at least the entire longitudinal direction of the active layer 120. The side insulating layer 170 may be formed to cover not only the active layer 120, but also a portion or the entirety of the longitudinal direction of the first conductive semiconductor layer 110 and/or the second conductive semiconductor layer 130. Preferably, the insulating layer 170 may be formed to cover the entire longitudinal directions of both the first conductive semiconductor layer and the second conductive semiconductor layer.

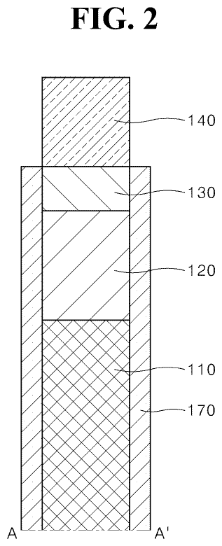

Thereafter, a rod-type light emitting device, as illustrated in the example of FIG. 2, may be manufactured through a device separation process.

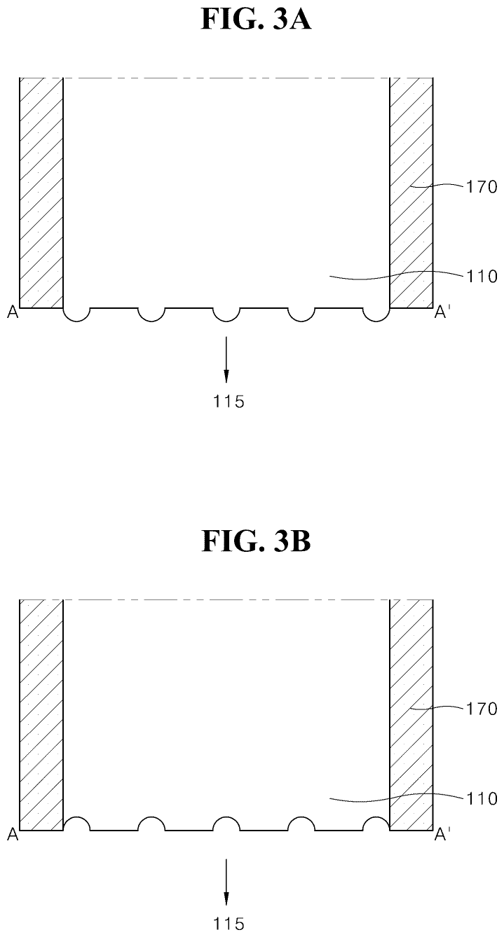

FIG. 2 schematically illustrates a rod-type light emitting device for a display apparatus according to the present disclosure. FIGS. 3A to 3C are views showing in more detail a portion A-A′ of FIG. 2.

Referring to FIGS. 2 and 3, the rod-type light emitting device for a display apparatus according to the present disclosure includes a first conductive semiconductor layer 110, an active layer 120 formed on the first conductive semiconductor layer, and a second semiconductor layer 130 formed on the active layer.

A side insulating layer 170 is formed to cover at least the entire longitudinal direction of the active layer 120. The side insulating layer 170 may be extended to cover at least a portion of the longitudinal direction of the first conductive semiconductor layer 110 and/or at least a portion of the longitudinal direction of the second conductive semiconductor layer 130.

Meanwhile, the first conductive semiconductor layer may be an n-type conductive semiconductor layer, and the second conductive semiconductor layer may be a p-type semiconductor layer.

In addition, a transparent electrode may be further included on the p-type second conductive semiconductor layer 130.

Notably, in the rod-type light emitting device according to the present disclosure, a lower surface of the first conductive semiconductor layer 110 is an uneven surface including irregular portions 115. In the example illustrated in FIG. 3A, a plurality of protrusion-shaped irregular portions are formed, in the example illustrated in FIG. 3B, a plurality of depression-shaped irregular portions are formed, and in the example illustrated in FIG. 3C, wave-shaped irregular portions are formed. Although not illustrated, the irregular portions may be a mixed form including two or more of protrusions, depressions, and waves. Such irregular portions 115 may be obtained, for example, by adjusting the frequency of the transducer and the height of the rod separation region during the device separation process as described above.

The irregular portions 115 on the lower surface of the first conductive semiconductor layer 110 may cause diffuse reflection of photons generated from the active layer, thereby improving light extraction efficiency. Meanwhile, the irregular portions 115 on the lower surface of the first conductive semiconductor layer 110 may be irregular. Of course, they may also be regularly formed, but in the present disclosure, since the device separation is performed using the penetration of microbubbles, the irregular portions 115 on the lower surface of the first conductive semiconductor layer 110 may be irregularly formed.

In the device separation step, the plurality of rods with the side insulating layer formed are separated from the substrate.

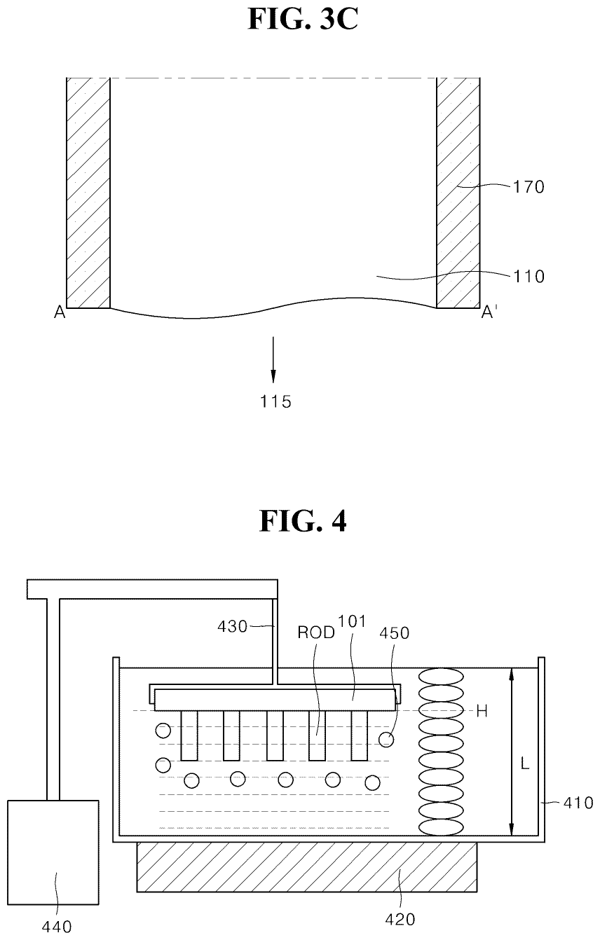

FIG. 4 schematically illustrates a device that may be used in a separation process of a rod-type light emitting device according to an embodiment of the present disclosure.

More specifically, in the device separation step, as illustrated in the example of FIG. 4, a substrate 101 on which a plurality of rods ROD are formed is inserted into a container 410 in which an organic solvent is stored and to which a transducer 420 is coupled. A high frequency is applied from the transducer 420 to the organic solvent to generate a plurality of microbubbles 450, and the plurality of microbubbles 450 gradually penetrate from edges of the plurality of rods toward their centers, thereby separating each of the plurality of rods from the substrate.

At this time, it is preferable that the transducer applies a high frequency of 80 to 160 KHz.

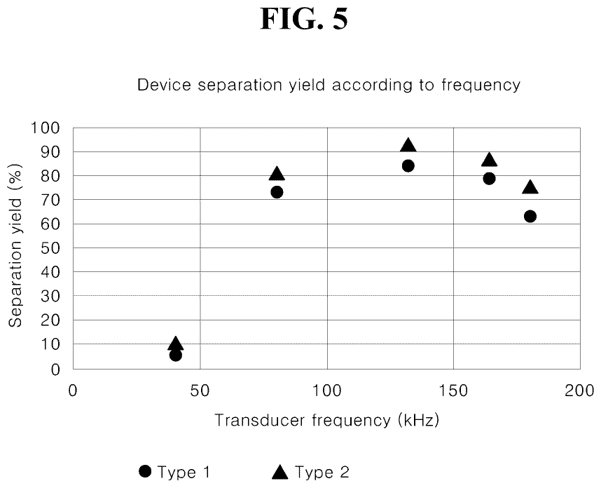

FIG. 5 is a graph showing the separation yield of the rod-type light emitting device according to transducer frequency.

As can be seen from the experimental results of FIG. 5, when the high frequency applied from the transducer 420 is less than 80 kHz, the separation yield is significantly low. This appears to be because, at low frequencies, the size of the microbubbles is relatively large. Meanwhile, although the high frequency applied from the transducer 420 shows a high separation yield up to 160 kHz, the yield gradually decreases thereafter, which appears to be because, at excessively high frequencies, the size of the microbubbles becomes too small to significantly affect the plurality of rods.

Meanwhile, when the substrate is inserted, it is preferable to insert the substrate 101 into the container 410 such that the plurality of rods face downward, as illustrated in the example of FIG. 4. The plurality of rods may be supported by a jig apparatus 430 and 440.

In FIG. 5, “Type 1” is a case in which the plurality of rods are inserted into the container 410 facing upward, and “Type 2” is a case in which the plurality of rods are inserted into the container 410 facing downward. Since Type 2 shows a relatively higher separation yield compared to Type 1, it may be considered more preferable.

Meanwhile, as illustrated in the example of FIG. 4, when the plurality of rods are inserted into the container 410 facing downward, a height H of ends of the plurality of rods adjacent to the substrate may be adjusted to a position of a node of a standing wave. Through this, the effects of microbubble generation by high frequency and wave energy (shock wave) may be maximized.

The position of the node of the standing wave may be determined by the following Equations 1 and 2.

$$Ultrasonic wavelength ( λ ) = Speed of ultrasound in organic solvent ( v ) / Frequency of transducer ( f ) \qquad [ Equation 1 ]$$

$$Node position of standing wave ( cm ) = n \times Ultrasonic wavelength ( λ ) / 2 , where n is an integer from 1 to 10 . \qquad [ Equation 2 ]$$

For example, when the frequency (f) of the transducer is 132 kHz and the speed of ultrasound in the organic solvent is 1125 m/s, the wavelength (λ) of the ultrasound is calculated as (1.13×10³ m/s)/(1.32×10⁵/s)=0.86 cm. To calculate the position of the node of the standing wave (cm), when the integer n is set to 3, the node position of the standing wave is calculated as 3×λ/2=1.29 cm.

As described above, in the method for manufacturing a rod-type light emitting device for a display apparatus according to the present disclosure, irregular portions may be formed on a lower surface of the first conductive semiconductor layer during the device separation process without adding a separate etching process, and through the irregular portions of the lower surface of the first conductive semiconductor layer, effects such as improvement in light extraction efficiency and enhancement of adhesion through improvement in contact area with an electrode may be obtained.

In addition, in the method for manufacturing a rod-type light emitting device for a display apparatus according to the present disclosure, high separation yield may be achieved by adjusting the frequency of the transducer and adjusting the height of ends of the plurality of rods corresponding to the separation part from the substrate.

While the above description has been made with reference to embodiments of the present disclosure, various modifications and alterations may be made by those skilled in the art. Such modifications and alterations are to be construed as falling within the scope of the present disclosure, as long as they do not depart from the scope of the present disclosure. Therefore, the scope of rights of the present disclosure shall be determined by the claims set forth below.

1. A method for manufacturing a rod-type light emitting device, comprising:
(a) sequentially forming a first conductive semiconductor layer, an active layer, and a second conductive semiconductor layer on a substrate;
(b) forming a mask pattern on the second conductive semiconductor layer;
(c) forming a plurality of rods by etching down to the first conductive semiconductor layer using the mask pattern by a dry etching method;
(d) forming an insulating layer on side surfaces of the plurality of rods so as to cover at least the entire longitudinal direction of the active layer; and
(e) separating each of the plurality of rods from the substrate,
wherein the step (e) comprises: inserting a result of the step (d) into a container in which a transducer is coupled and an organic solvent is stored, applying a high frequency from the transducer to the organic solvent to generate a plurality of microbubbles, and separating each of the plurality of rods from the substrate as the plurality of microbubbles gradually penetrate from edges of the plurality of rods toward their center,
wherein in the step (e), the transducer applies a high frequency of 80 to 160 KHz.

2. (canceled)

3. The method for manufacturing a rod-type light emitting device according to claim 1,
wherein in the step (e), the substrate is inserted into the container such that the plurality of rods face downward.

4. The method for manufacturing a rod-type light emitting device according to claim 3,
wherein in the step (e), a height of ends of the plurality of rods adjacent to the substrate is adjusted to a position of a node of a standing wave.

5. The method for manufacturing a rod-type light emitting device according to claim 1,
wherein the first conductive semiconductor layer is an n-type conductive semiconductor layer, the second conductive semiconductor layer is a p-type conductive semiconductor layer, and
the step (a) further comprises a step of forming a transparent electrode on the second conductive semiconductor layer.

6. The method for manufacturing a rod-type light emitting device according to claim 1, further comprising:
after the step (c), additionally etching side surfaces of the plurality of rods by a wet etching method to reduce a difference in lateral size between upper and lower portions of the plurality of rods.

7. The method for manufacturing a rod-type light emitting device according to claim 1,
wherein in the step (d), the insulating layer is formed of a material including at least one of silicon oxide (SiOₓ), silicon nitride (SiNₓ), silicon oxynitride (SiONₓ), and aluminum oxide (Al₂O₃).

8. The method for manufacturing a rod-type light emitting device according to claim 1,
wherein in the step (d), the insulating layer is formed to include a hydrophobic surface.

9. The method for manufacturing a rod-type light emitting device according to claim 8,
wherein in the step (d), the insulating layer includes an inorganic insulating layer and an organic insulating layer formed on the inorganic insulating layer, and a terminal of the organic insulating layer has a hydrophobic functional group.

10. The method for manufacturing a rod-type light emitting device according to claim 9,
wherein the hydrophobic functional group includes an alkyl group of C1 to C18.

11. The method for manufacturing a rod-type light emitting device according to claim 1,
wherein in the step (d), the insulating layer is formed to cover the entire longitudinal directions of the first conductive semiconductor layer and the second conductive semiconductor layer.

12-19. (canceled)
